(19) United States
(12) Patent Application Publication
(10) Pub. No.: US 2009/0273352 A1
(43) Pub. Date: Nov. 5, 2009

(54) SENSOR APPARATUS AND SYSTEM FOR TIME DOMAIN REFLECTOMETRY

(76) Inventor: XIONG YU, Beachwood, OH (US)

Correspondence Address: TAROLLI, SUNDHEIM, COVELL & TUMMINO, LLP, 1300 EAST NINTH STREET, SUITE 1700, CLEVELAND, OH, 44114, US

(21) Appl. No.: 12/432,130

(22) Filed: Apr. 29, 2009

Related U.S. Application Data
(60) Provisional application No. 61/049,187, filed on Apr. 30, 2008.

(51) Int. Cl. G01R 27/04

(52) U.S. Cl. 324/644

(57) ABSTRACT

A sensor probe for time domain reflectometry may include a plurality of flexible elongated strips of an electrically conductive material extending from a proximal end portion of the probe to a distal end portion thereof. Each of the elongated strips can be substantially coplanar relative to each other along a path that is transverse to a longitudinal axis of the probe, and the plurality of elongated strips also being in a substantially parallel arrangement along the length of the probe. A flexible substrate of an insulating material can be attached to the sheets to maintain the sheets in the substantially parallel and coplanar arrangement. A connector is electrically coupled to the strips for providing communication of electrical signals relative to the strips.

### RELATED APPLICATION

This application claims the benefit of U.S. provisional patent application No. 61/049,187, which was filed on 30 Apr., 2008, and entitled TIME DOMAIN REFLECTOMETRY FOR MONITORING GEOSTRUCTURES AND ENVIRONMENTAL CHARACTERISTICS, the entire contents of which is incorporated herein by reference.

### TECHNICAL FIELD

The invention relates generally to measurement and, more specifically, to a sensor probe and system for time domain reflectometry.

### BACKGROUND

Time domain reflectometry (TDR) is a guided electromagnetic wave technology, which can measure electrical characteristics and provide an indication of material properties and conditions based on the speed and attenuation of an electromagnetic wave. TDR works by generating a small-magnitude electromagnetic field excitation and measuring the response. Dipoles (originated from the molecular geometry or charges of the particles) oscillate under the excitation. The overall responses of the material are dependent on the excitation frequencies and is described by the dielectric spectra. Certain ions drift freely under the electrical field and the macroscopic phenomena correspond to electrical conductivity.

Typical information obtained from a TDR signal includes the apparent dielectric constant, Ka and electrical conductivity, Ec. Each of these parameters provides information about the materials surrounding the probe. For instance, the travel time for a pulsed electromagnetic signal along a TDR probe, corresponding to the apparent dielectric constant (Ka), can be expressed as follows:

$$Ka = {( \frac{{l}_{a}}{L} )}^{2}$$

where lₐ is the apparent length, which may be determined from analyzing a time lapse between reflections at ends of the probe; and
L is length of the wave guide.

TDR was originally used by electrical engineers for locating discontinuities in electrical lines by observing reflected waveforms. It is being increasingly used for civil and environmental applications since TDR can determine the permittivity (dielectric constant) of a material from wave propagation. Because there is a strong relationship between the permittivity of a material and its water content, for example, TDR can be employed determine moisture content porous media, including in soils.

A typical TDR system for civil and environmental applications includes a probe that is made of two or more parallel metal rods embedded in a soil or sediment. TDR probes are usually between 10 and 30 cm in length and connected to TDR electronics, such as via a coaxial cable. Since existing TDR sensor probes generally only make point measurement of soil characteristics, multiplexing multiple TDR sensor probes is needed to ascertain an understanding over a larger area. The greater number of probes, however, tends to increase the overall cost and requires careful plan for sensor probes installation and management. Additionally, the spatial distribution of moisture content is not available or can only be crudely estimated from such a spatial arrangement of probes by interpolating the measurements at discrete locations where the probes are positioned.

Despite the large number of applications for TDR technology, research efforts in understanding the fundamentals of electromagnetic wave propagation in a TDR system still appear quite limited. Lack of progresses in this area lead to the consequence that the advantages of TDR for distributive measurement have not been fully utilized. Additionally, efforts seem to have neglected many practical limitations of TDR, which are increasingly important for commercial applications.

### SUMMARY

The invention relates generally to measurement and, more specifically, to a sensor probe and system for time domain reflectometry.

One aspect of the invention provides a sensor probe for time domain reflectometry. The probe may include a plurality of flexible elongated strips of an electrically conductive material extending from a proximal end portion of the probe to a distal end portion thereof. Each of the elongated strips can be substantially coplanar relative to each other along a path that is transverse to a longitudinal axis of the probe, and the plurality of elongated strips also being in a substantially parallel arrangement along the length of the probe. A flexible substrate of an insulating material can be attached to the sheets to maintain the sheets in the substantially parallel and coplanar arrangement. A connector is electrically coupled to the strips for providing communication of electrical signals relative to the strips. The sensor probe can be used in a TDR system for a variety of applications.

### BRIEF DESCRIPTION OF THE DRAWINGS

FIG. 1 depicts an example of a sensor probe.

FIG. 2 depicts an example of the sensor probe of FIG. 1 taken along the lines 2-2.

FIG. 3 depicts an example of part of a sensor probe illustrating a connection interface relative to the probe.

FIG. 4 depicts an example of a distal end of a sensor probe according to one embodiment.

FIG. 5 depicts an example of a distal end of a sensor probe according to another embodiment.

FIG. 6 depicts an example embodiment of a TDR system illustrating the sensor probe positioned vertically for sensing characteristics in a subgrade.

FIG. 7 depicts another example embodiment of a TDR system illustrating the sensor probe positioned horizontally for sensing characteristics in a subgrade.

FIG. 8 depicts yet another embodiment of a TDR system illustrating the sensor probe is positioned laterally such as for sensing characteristics at or near a surface.

FIG. 9 depicts still another embodiment of a TDR system illustrating the sensor probe attached to a curved surface.

FIG. 10 depicts an example of a schematic block diagram of a TDR system.

### DETAILED DESCRIPTION

The invention relates generally to a sensor probe and system for time domain reflectometry (TDR). In one embodiment, the probe includes a plurality (e.g., two or more) substantially flat and elongated strips of electrically conductive material. Each of the strips is disposed in a substantially parallel arrangement relative to each other along the length of the probe. The probe is configured such that the strips remain substantially coplanar along a path that is transverse to a longitudinal axis of the probe, which axis may follow a linear or curved path. The contour of the longitudinal axis of the probe, for example, can vary depending on application requirements and use conditions that may remain constant or may change over time. A flexible substrate can be applied to the strips such as to maintain the structural relationship of the strips. A TDR probe having such a configuration can be manufactured at a reduced cost relative to many existing TDR probes. Additionally, the configuration can be manufactured at lengths ranging from centimeters to kilometers to accommodate virtually any application.

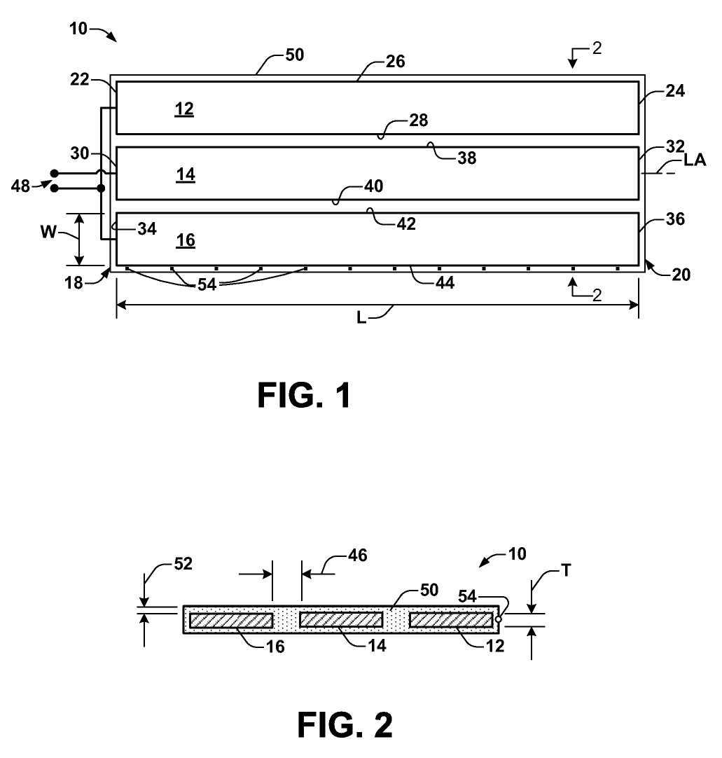

Turning to the figures, FIGS. 1 and 2 depict an example of a sensor probe 10 that can be implemented according to an aspect of the invention. As shown in FIG. 1, the sensor probe 10 includes a plurality of sensor strips 12, 14 and 16 formed of an electrically conductive material. Each of the strips 12, 14 and 16 can be formed of a highly electrically conductive material, such as steel, copper, aluminum, metal alloys or other material suitable for operating as a waveguide for transmission of electrical RF signals. The strips 12, 14 and 16 extend in a substantially parallel relationship from a proximal end portion 18 of the probe to a distal end portion 20 thereof. As used herein, in the context of structural configuration, the term “substantially” reflects that while the sheets of the probe may be designed to have a stated configuration, manufacturing tolerances and external forces to which the probe may be exposed during use can cause slight variations (e.g., about +/−5%) from the intended configuration.

Each of the elongated strips 12, 14 and 16 is also substantially coplanar (or flat) relative to each other along a path (e.g., section line 2-2) that is transverse to a longitudinal axis LA of the probe 10. The strip 12 has a proximal end 22 and a distal end 24 spaced apart from each other by respective side edges 26 and 28 of the respective strip. Each of the other strips 14 and 16 are similarly configured with respective ends 30, 32, 34 and 36 and side edges 38, 40, 42 and 44. Each of the strips 12, 14 and 16 also has a length (L) between its ends and a width (W) corresponding to the distance between the side edges of each given strip. Each of the strips 12, 14 and 16 also has a thickness (T) that is less than its width. Each of the strips 12, 14 and 16 can be dimensioned and configured to be substantially identical (e.g., having substantially the same length, width and thickness), although this is not required. For instance, in certain implementations, one or more of the strips can have a different length from the other strips. As used herein, the term “strip” refers a relatively long and narrow piece of the material such that L is much greater than W. For instance, L will be greater than W by at least a factor of 10 (e.g., L>10*W>T).

FIG. 2 is a cross-sectional view of the probe 10 taken along section line 2-2 demonstrating that each of the strips 12, 14 and 16 can have a generally rectangular cross-sectional configuration. While FIG. 2 is not drawn to scale, it will be appreciated that the width can be much greater than the thickness such that the strips can be considered generally flat (e.g., W≧10*T). A distance between adjacent side edges (28 and 38 as well as edges 40 and 42) of each adjacent pair of the strips defines a gap between the strips, indicated at 46. The gap 46 between adjacent strips can be substantially constant along the length of the probe 10. The dimensions of each strip 12, 14 and 16 can vary according to application requirements.

The probe 10 includes a connector 48 that is electrically coupled at the proximal end 18 to each of the strips 12, 14 and 16. The connector 48 can be configured for providing a communication path for electrical signals relative to and from the strips, such as can be connected to a TDR device. In the example of FIG. 1, the connector 48 includes two terminals, one of which is electrically coupled to strips 12 and 16 and the other of which is coupled to the center strip 14. In one embodiment, the width of each of the strips 12, 14, and 16 and the gap 46 between each adjacent pair of the strips are dimensioned and configured to provide an impedance for the sensor probe 10 that substantially matches the impedance of the connector 48 (e.g., 50Ω or 75Ω).

The relative orientation and position of each of the respective strips 12, 14, and 16 can be maintained by securing such strips to a flexible substrate, indicated at 50. The flexible substrate can be formed of an insulating material having a relative static permittivity as to provide a high dielectric constant for the material over a desired frequency range and operating conditions. For example, the flexible substrate 50 can have a relative static permittivity greater than 1, such as about 5 or greater.

The flexible substrate 50 can have a thickness (52) from the planar surface of the strips 12, 14 and 16, which thickness can vary according to design requirements and the intended use of the probe. In addition to maintaining the relative configuration and arrangement of the strips 12, 14 and 16, such substrate can provide resistance to abrasion, moisture, alkalies, acid, which might occur due to the varying environmental conditions in which the probe may be used. Thus, the insulating layer can help ensure integrity of the probe for extended periods of monitoring (e.g., a period of years). As an electrically insulating material, the substrate 50 can also mitigate energy loss that might otherwise occur as the signals propagate along the length of the strips. Coating the sensor with high dielectric insulation material, such as polymers or ceramic materials, thus prevents energy attenuation without sacrificing sensitivity of the probe for measuring properties of surrounding materials.

As one example, the flexible substrate 50 can be implemented as one or more layers of an electrically insulating and corrosion resistant tape (e.g., a polyester film, electrical insulating tape). The tape can include a layer of insulating backing material and an insulating adhesive layer. For example, the tape can be applied over and secured a planar surfaces of the strips. To facilitate maintaining the orientation of the strips as the tape is applied, the strips 12, 14 and 16 can be held in place, such as by a mandrel or other holding device having slots dimensioned and configured to hold the strips in a desired orientation. Such a fabrication method can be implemented manually or by an automated or semi-automated manufacturing process. The tape can be applied for example as a single sheet of tape that is applied to one surface of the strips and then folded over both planar surfaces of the strips. Alternatively, two sheets of the tape can be applied—one sheet applied to each surface—to effectively sandwich the arrangement of strips therebetween. Those skilled in the art will understand other approaches that can be utilized to apply tape or other substrate to fix the relative position of the strips 12, 14 and 16.

A high dielectric insulating material such as the tape or other material (e.g., epoxy or polymer coating) can be applied to the strips 12, 14 and 16 in a variety of ways. For example, the insulating material may itself form the substrate 50, such as the tape described herein. Alternatively, a coating of an insulating material can be applied to the surface of each strip 12, 14 and 16 in combination with the substrate 50 that maintains the spatial arrangement of the strips. That is, multiple layers and types of materials can be utilized in the sensor probe 10 to provide desired structural and corrosion resistance properties.

As mentioned, above, the flexible substrate 50 maintains the strips in a desired orientation along the length of the sensor probe 10. Because each of the strips is formed of a flexible material and are attached to a flexible substrate 50, the sensor probe 10 can be bent to accommodate a variety of shapes, such as including curves, arcs, circles or spiral and the like. That is, as used herein, the term “flexible” means that, the strips and covering of the probe have mechanical properties that permit bending or flexing of the probe bent without breaking or fracturing. The strips thus can be sufficiently flexible such that a length of the sensor probe can be rolled on itself (or coiled) to facilitate transport or storage.

Besides serving as TDR waveguide for electromagnetic waves, the probe 10 can be modified to provide for sensing of other environmental conditions. For example, other sensors, indicated at 54, can be integrated along the probe 10 to simultaneously measure other conditions, such as thermocouples to measure the temperature distribution along the length of the probe. For example, a plurality of the sensors 54 can be attached to one or more of the strips 12, 14 and 16 and/or be attached the substrate 50 in a spaced apart relationship along the length of the probe 10. The sensors 54 can provide respective signals via the connector 48 or another output connection (not shown). It will be appreciated that the addition of temperature sensors can expand the sensing capabilities of a TDR system employing the probes, such as to investigate special regional issues such as freeze-thaw damage of pavements located in cold regions. The same sensor can also serve as carrier for other environmental sensors to measure the humidity, salinity and soil suctions. Fusion of these environmental parameters can help study the effects of a variety of underground environmental factors on the dielectric properties (e.g., moisture) monitored by via the strips 12, 14 and 16. For instance, a measured temperature can also be used in the computations for the dielectric constant, such as to afford a greater degree of accuracy.

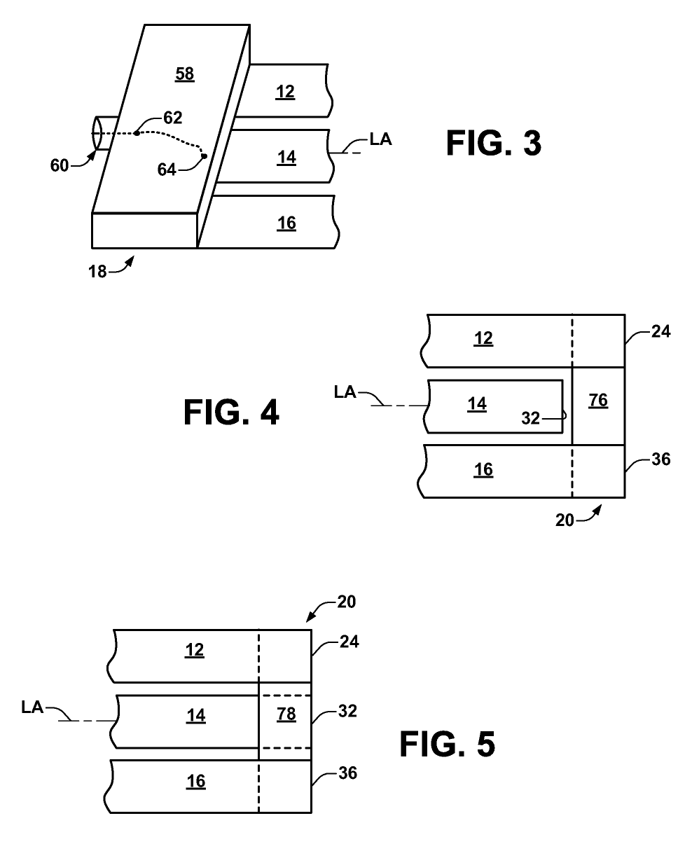

FIG. 3 depicts an example embodiment of the proximal end portion 18 that can be implemented for the sensor probe 10. The end portion 18 includes a connector bracket 58 that is physically attached across the strips 12, 14 and 16. The bracket 58 can be formed of an electrically conductive material that is dimensioned and configured (e.g., as a substantially solid rectangular cube) to extend across and contact each of the strips 12, 14 and 16. The material of the bracket 58 can be formed of the same or different material from the sensor strips 12, 14 and 16 (e.g., a highly electrically conductive material).

The proximal end portion 18 also includes a connector 60 that extends outward from the bracket 58, such as illustrated in FIG. 3. The connector 60 is dimensioned and configured to connect the sensor probe to a TDR device, such as described herein. The connector 60 can provide for a differential input including a ground connection and a corresponding signal connection. For example, the connector 60 can be implemented as a coaxial cable connector that is electrically connected to the strips to provide for transmission and reception of signals relative to the probe 10.

In the example of FIG. 3, the signal connection of the connector 60 is electrically coupled to the central strip 14, which can be implemented by soldering connections 62 and 64 coupling a terminal of the connector 60 to the central strip 14. The central strip 14 can be electrically isolated from the bracket 58 by an insulating material interposed between the bracket 58 and the adjacent surface of the sensor strip 14. Each of the other sensor strips 12 and 16 can be electrically connected together via the bracket 58 or otherwise connected to each other at the proximal end. The bracket 58 can be further electrically connected to the another terminal of the connector 60, which for the example of a coaxial connector can correspond to the shield housing thereof.

FIGS. 4 and 5 depict different embodiments of the distal end portion 20 of the sensor probe 10 that can be implemented. It will be appreciated that different distal end configurations of FIGS. 4 and 5 can be utilized for different application requirements, such as for use in water or other high moisture environments and for drier conditions.

In the distal end portion 20 of FIG. 4, the strips 12 and 14 include respective distal ends 24 and 36 that are electrically connected together by an interconnecting transverse strip 76 of an electrically conductive material (e.g., the same material as the strips 12 and 14). The distal end 32 of the central strip 14 is electrically isolated and spaced apart from the connecting strip 76 and thus is isolated from the distal ends 24 and 36 by providing a suitable gap. The flexible substrate 50 helps to maintain the gap at the distal end portion 20. Thus, the strip 14 has a shorter length from the strips 12 and 16. The transverse strip can be attached across the ends or the structure can be formed as a monolithic structure having such configuration.

In the distal end portion 20 of FIG. 5, each of the distal end portions 24, 32 and 36 of the respective strips 12, 14 and 16 are electrically connected together (e.g., electrically shunted) by a corresponding electrical connection. For instance, a transverse strip 78 of electrically conductive material can be attached across the ends 24, 32 and 36 of the respective strips 12, 14 and 16.

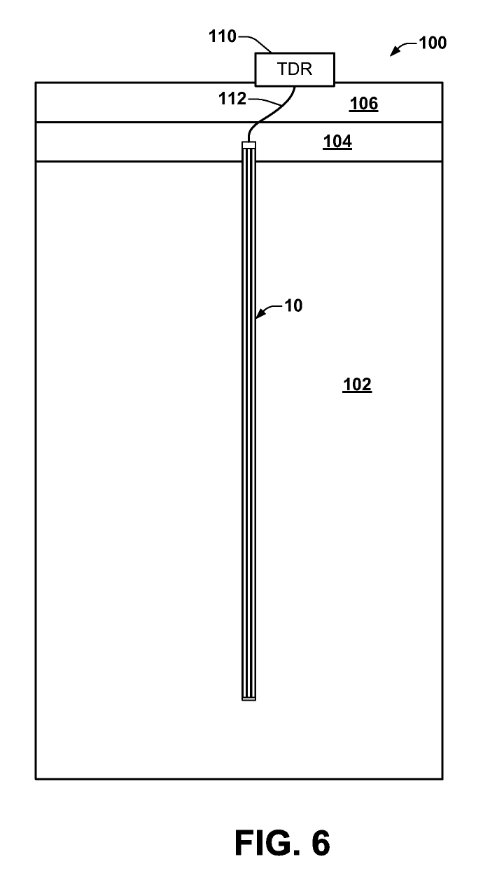

By way of further illustration, FIGS. 6, 7, 8 and 9 are embodiments depicting example applications of how a sensor probe 10 can be utilized for different types of measurements. The examples of FIGS. 6-9 are intended by way of example and are not to be construed as limiting, as those skilled in the art will appreciate various other uses of the probe based on the teachings herein.

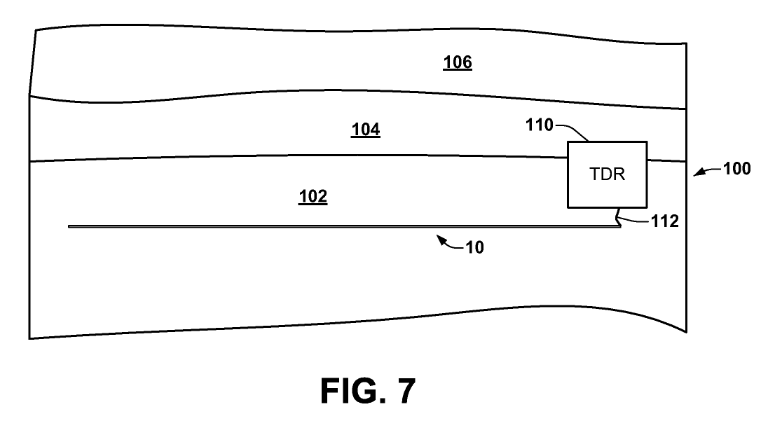

FIGS. 6 and 7 depicts a TDR system 100 that includes the sensor probe 10 positioned with a subgrade layer 102. The subgrade layer 102 is located beneath a base layer 104 and a top surface layer 106, which may be Portland cement concrete (PCC) or asphalt concrete (AC) layer. In FIG. 6, the probe 10 is positioned to extend vertically through the subgrade layer 102, such as can be placed in a bore hole that has been drilled by a user. The sensor probe 10 is communicatively coupled to a TDR device 110, such as via a coaxial or other cable 112. In the example of FIG. 6, the TDR device is positioned at the surface of the PCC/AC layer 106, although it could at different locations such as any of the layers 102, 104 or 106. Such an arrangement can be employed for monitoring monitoring moisture or other properties of the subgrade layer 102 at varying depths for a given location.

In FIG. 7, the probe 10 is positioned to extend laterally or horizontally in a direction that is substantially parallel to the surface. Thus, the arrangement of FIG. 7 can be be employed for monitoring monitoring moisture or other properties of the subgrade layer 102 at a given depth over an extended area. In the example of FIG. 7, the TDR device 110 is positioned at the juncture of the base and subgrade layers, although it could at different locations according to application requirements.

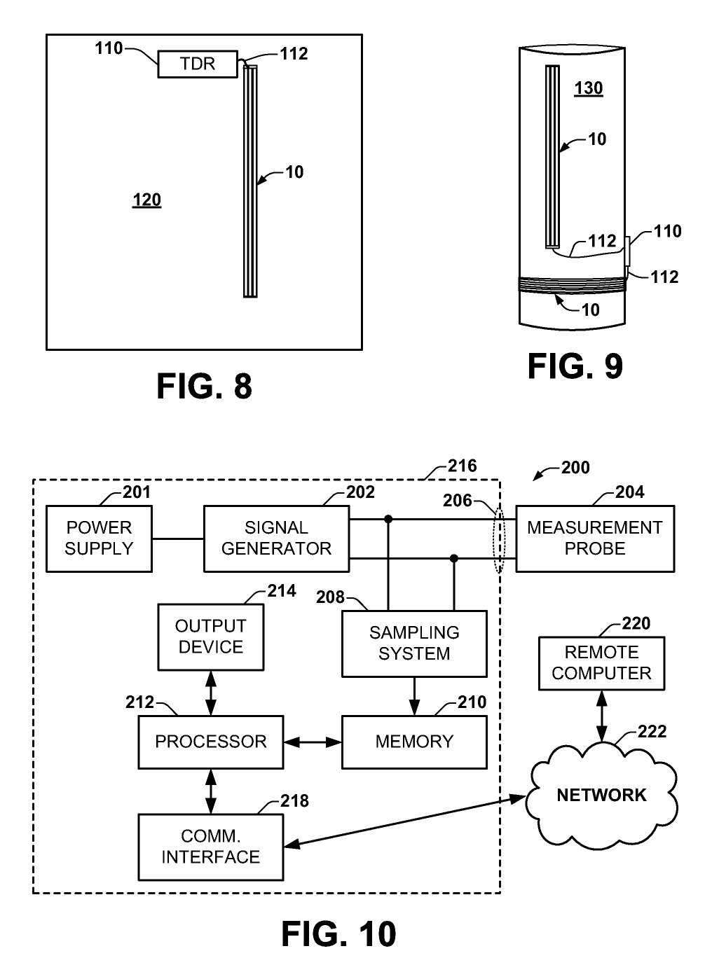

FIG. 8 depicts an example of the sensor probe 10 positioned at or near the surface 120 of a structure (e.g., soil, pavement, concrete, grass or the like). Advantageously, since the probe 10 is flexible it can adapt to and the contour of the surface 120 and remain in contact with the surface along its length. Alternatively, the probe can be buried near the surface, such as for sensing moisture content of soil or other landscaping applications (e.g., for irrigation monitoring). Due to the structural flexibility of the probe 10, the probe can easily adapt to the contours of the surface where it is initial positioned which may further change over time. The TDR device 110 can be at the surface or buried.

FIG. 9 depicts an example of a plurality of sensor probes 10 attached to a curved structure 130, such as pillar or support beam. As depicted, one of the probes 10 can be attached to the structure in a circumscribing or spiral arrangement about the structure 130. One or more other probes 10 can be attached to the structure 130 as extending vertically along the length of the structure. The probes can be on the surface of the structure 130 or be embedded therein, such as when implemented with new construction. The arrangements of FIG. 9 can be employed for monitoring bridge scour or other properties associated with the structure 130 or materials (e.g., soil) surrounding the structure.

In view of the foregoing examples, those skilled in the art will appreciate various uses of the probe. By way of example, the probe can be adapted for a variety of uses, such as including for monitoring changes in the soil modulus reductions, monitoring of moisture distribution, determining the curing status of concrete and stabilized soils, and for monitoring of bridge scour to name a few.

FIG. 10 depicts an example of a TDR system 200 that can be implemented according to an aspect of the invention. The TDR 200 includes a signal generator 202 that is configured to generate corresponding electrical pulses that is applied to a measurement probe 204 via an electrical connector schematically depicted at 206. The probe 204 can be implemented as the probe shown and described herein. A power supply 201 can power the TDR system 200, which can be a DC or AC supply according to application requirements. A single generator 202 can provide pulse with a suitable rise time to facilitate measurements and detections of pulses via TDR. The signal generator 202 can provide electrical pulse at a frequency (or frequencies) within a predetermined frequency range for TDR measurement (e.g., a range of about 1 MHz to about 4000 MHz, or at about 1000 MHz).

A sampling system 208 is electrically connected to the connector 206 to measure the transmitted and reflected pulses from the measurement probe 204. The sampling system 208 can perform the sampling of the reflected signal at a predetermined sample rate. The number of samples and hence the resolution of the TDR system 200 can be controlled according to the sample rate. The sample rate can be programmable.

The sampling system 208 can store the measurement data in memory 210. A processor, controller, or other logic device can be coupled to the memory 210 to compute an indication of the electrical characteristics based upon the measurements stored in the memory by the sampling system. For instance, the processor 212 can determine an indication of electrical characteristics (e.g., dielectric permittivity or relative permittivity) along the length of the probe according to known TDR methods. Additionally, temperature and/or environmental characteristics can be measured and utilized to enhance the TDR calculations.

The processor 212 can provide the TDR measurement data to an output device 214. The output device 214 can provide the respective sample data and/or the computed electrical characteristics over a period of time, which can be accessed and retrieved from the system 200. For example, the output device 214 can include a interface or connector that can be accessed through an external housing of the device, indicated at 216, to retrieve the TDR data that has been recorded over a period of time. The processor 212 can control the duration between measurement cycles to store an appropriate amount of TDR data according to application requirements. For instance the measurement cycle for irrigation control can be on the order of minutes or hours, whereas for monitoring scour, the measurement cycles can be on the order of days or weeks.

A communication interface 218 may also be connected to the processor 212 such as to communicate TDR data to a remote system. In the example of FIG. 10, the communication interface 218 is in communication with one or more remote computer 220 via a network 222. The communication between the communication interface 218 and the network 222 can be implemented via electrically conductive, fiber links or through wireless communication means (e.g., cellular data network, 802.11x or WiMax). Those skilled in the art will appreciate various types of communication means that can be utilized for communicating TDR data to the remote computer 220. The remote computer can be utilized to remotely program the device as well to retrieve TDR data.

As will be appreciated by those skilled in the art, portions of the system 200 may be embodied as a method, data processing system, or computer program product. Accordingly, these portions of the present invention may take the form of an entirely hardware embodiment, an entirely software embodiment, or an embodiment combining software and hardware. Furthermore, portions of the invention may be a computer program product on a computer-usable storage medium having computer readable program code on the medium. Any suitable computer-readable medium may be utilized including, but not limited to, static and dynamic storage devices, hard disks, optical storage devices, and magnetic storage devices.

What have been described above are examples and embodiments of the invention. It is, of course, not possible to describe every conceivable combination of components or methodologies for purposes of describing the invention, but one of ordinary skill in the art will recognize that many further combinations and permutations of the present invention are possible. Accordingly, the invention is intended to embrace all such alterations, modifications and variations that fall within the scope of the appended claims. In the claims, unless otherwise indicated, the article “a” is to refer to “one or more than one.”

What is claimed is:

1. A sensor probe for time domain reflectometry, comprising:
a plurality of flexible elongated strips of an electrically conductive material extending from a proximal end portion of the probe to a distal end portion thereof, each of the elongated strips being substantially coplanar relative to each other along a path that is transverse to a longitudinal axis of the probe, the plurality of elongated strips also being in a substantially parallel arrangement along a length of the probe;
a flexible substrate of an insulating material overlying and attached to the plurality of elongated strips to maintain the plurality of elongated strips in the substantially parallel and coplanar arrangement; and
a connector electrically coupled to each of the plurality of elongated strips for providing communication of electrical signals relative to the plurality of elongated strips.

2. The sensor probe of claim 1, wherein each of the plurality of elongated strips have proximal and distal ends spaced apart from each other by side edges of the respective strip, a distance between the side edges of each strip defines a width of the respective strip, each of the plurality of elongated strips having a thickness that is less than the width.

3. The sensor probe of claim 2, wherein a distance between adjacent side edges of each adjacent pair of the plurality of elongated strips defines a gap that is substantially constant along the length of the probe.

4. The sensor probe of claim 3, wherein the connector has an input impedance, the width of each of the plurality of elongated strips and the gap between each adjacent pair of the plurality of elongated strips are dimensioned and configured to provide an impedance for the sensor probe that substantially matches the input impedance of the connector.

5. The sensor probe of claim 4, wherein each of the plurality of elongated strips has substantially the same length, width and thickness.

6. The sensor probe of claim 3, wherein each of the plurality of elongated strips comprises a substantially flat sheet of the electrically conductive material having a substantially rectangular cross sectional configuration.

7. The sensor probe of claim 1, further comprising a connector bracket attached to each of the plurality of elongated strips at the proximal end portion of the probe, the connector being attached to and extending from the connector bracket, the connector bracket being electrically connected to at least two of the plurality of elongated strips while being electrically isolated from at least one other of the plurality of elongated strips.

8. The sensor probe of claim 7, wherein the connector comprises coaxial cable connector.

9. The sensor probe of claim 1, wherein the plurality of flexible elongated strips further comprises at least three strips, at least two of the three strips being electrically connected to each other by a connection located at the distal end portion of the sensor probe.

10. The sensor probe of claim 9, wherein another of the three strips is electrically isolated from the at least two of the three strips at the distal end portion of the sensor probe.

11. The sensor probe of claim 1, wherein each of the plurality of elongated strips is electrically connected to each other by a connection located at the distal end portion of the sensor probe.

12. The sensor probe of claim 1, further comprising:
a measurement device coupled to the sensor probe via the connector, the measurement device comprising:
a signal generator coupled to provide a signal to the sensor probe; and
a sampling system configured to sample signals from the sensor probe and to store an indication of sampled signals.

13. The sensor probe of claim 1, wherein the flexible substrate comprises a corrosion resistant and electrically insulating material that completely covers the plurality of elongated strips and maintains the substantially parallel and coplanar arrangement along the length of the probe.

14. A time domain reflectometry system, comprising:
a sensor probe comprising:
a plurality of flexible elongated strips of an electrically conductive material extending from a proximal end portion of the probe to a distal end portion thereof, each of the elongated strips being substantially coplanar relative to each other along a path that is transverse to a longitudinal axis of the probe, the plurality of elongated strips also being in a substantially parallel arrangement along a length of the probe;
a flexible layer of an electrically insulating material overlying and attached to the plurality of elongated strips to maintain the plurality of elongated strips in the substantially parallel and coplanar arrangement; and
a connector electrically coupled to each of the plurality of elongated strips for providing communication of electrical signals relative to the plurality of elongated strips; and
a TDR unit communicatively coupled to the probe via the connector, the TDR unit being configured to transmit a TDR signal to the probe and monitor a response, the TDR unit being configured to sample signals from the sensor probe and store an indication of the sampled signals in memory.

15. The system of claim 14, wherein each of the plurality of elongated strips have proximal and distal ends spaced apart from each other by side edges of the respective strip, a distance between the side edges of each strip defines a width of the respective strip, each of the plurality of elongated strips having a thickness that is less than the width.

16. The system of claim 15, wherein a distance between adjacent side edges of each adjacent pair of the plurality of elongated strips defines a gap that is substantially constant along the length of the probe.

17. The system of claim 16, wherein the connector has an input impedance, the width of each of the plurality of elongated strips and the gap between each adjacent pair of the plurality of elongated strips are dimensioned and configured to provide an impedance for the sensor probe that substantially matches the input impedance of the connector.

18. The system of claim 14, wherein each of the plurality of elongated strips has substantially the same length, width and thickness.

19. The system of claim 13, further comprising a connector bracket attached to each of the plurality of elongated strips at the proximal end portion of the probe, the connector being attached to and extending from the connector bracket, the connector bracket being electrically connected to at least two of the plurality of elongated strips while being electrically isolated from at least one other of the plurality of elongated strips.

20. The system of claim 19, wherein the connector is attached to and extends from the connector bracket, wherein at least two of the plurality of elongated strips are electrically connected together by a first connection at the proximal end portion of the sensor probe, at least one other of the plurality of elongated strips being electrically isolated from the at least two of the plurality of elongated strips at the proximal end portion and being one of electrically connected or electrically isolated from the at least two of the plurality of elongated strips at a distal end portion of the sensor probe.
